(19) United States
(12) Patent Application Publication
(10) Pub. No.: US 2016/0065149 A1
(43) Pub. Date: Mar. 3, 2016

(54) Low Noise Amplifier Method and Apparatus

(71) Applicant: COMMONWEALTH SCIENTIFIC AND INDUSTRIAL RESEARCH ORGANISATION, Australian Capital Territory (AU)

(72) Inventor: Robert Douglas Shaw, Marsfield (AU)

(21) Appl. No.: 14/888,431

(22) PCT Filed: May 2, 2014
(86) PCT No.: PCT/AU14/00484

§ 371 Date: Oct. 31, 2015

(30) Foreign Application Priority Data
May 2, 2013 (AU) 2013901548

(51) Int. Cl. H03F 1/56; H03F 3/45

(52) U.S. Cl. CPC H03F 1/565; H03F 3/45076; H03F 2203/45154; H03F 2200/294

(57) ABSTRACT

A low noise amplifier circuit including: at least a first input and first output; at least a first stage of transistor amplification having a transistor input terminal; the circuit further comprising: an input driving circuit interconnecting the first input to the transistor input terminal, the input driving circuit including a parallel resonant circuit interconnected between the transistor input terminal and ground and a series resonant circuit interconnected between the input terminal and the transistor input terminal, the input driving circuit functioning as an input matching network for the circuit in conjunction with an input bias and decoupling network.

### FIELD OF THE INVENTION

The present invention relates to the field of low noise amplifiers, and in particular, discloses a wide bandwidth low noise amplifier suitable for use in a non-cryogenic environment. Additionally, the present invention has particular suitability for utilisation in self complementary phased array feeds utilised in radio astronomy.

### BACKGROUND

Any discussion of the background art throughout the specification should in no way be considered as an admission that such art is widely known or forms part of common general knowledge in the field.

Applications of low-noise amplifiers are many and varied. However, one particular application is for the amplification of weak detected signals in radio astronomy or sensing.

Low-noise amplifiers are generally designed for a nominal system impedance of a certain value over at least the bandwidth of operation. This impedance is normally independent of frequency. Often it is 50 ohms, and sometimes 75 ohms. This state of affairs comes about for two reasons, firstly, that measurement equipment operates at 50 ohm impedance; and secondly, that the feed to which the low-noise amplifier's input connects is normally designed for a 50 ohm impedance. Normally, an antenna feed and the low-noise amplifier are both optimised to present to one other an impedance as close to 50 ohms as possible. This is done for ease of design and ease of measurement, since both components need to be compatible with measurement equipment. Of course, other standard values could be chosen.

The standardisation of choice on a 50 ohm system impedance also normally dictates the use of coaxial transmission lines at the amplifier's input and output ports. A coaxial transmission line features a signal conductor and a ground conductor, and by its nature requires an amplifier connected to it to be single-ended, meaning it has one (non-ground) input conductor and one non-ground output conductor.

In the state of the art, provision is usually made for matching networks between the amplifier's input port and the amplifying transistor's input on the one hand, and the amplifier's output port and the amplifying transistor's output on the other hand. The input matching network is designed for best compromise between impedance match and noise match, while the output matching network is generally optimised for impedance match. Again, these networks are designed to match the transistors utilised to a system impedance of 50 ohms over the intended frequency band.

In contrast to the single-ended amplifier, a differential amplifier has two non-ground input conductors, driven out of phase. A differential amplifier may also have two output conductors, with a 180-degree phase relationship between them. Differential low-noise amplifiers are in the state of the art, but are considerably less employed than their single-ended counterparts, because they require connection to a balanced feed structure. A complementary antenna structure, such as a chequerboard phased-array feed is one such structure.

An example of one such self complementary array taking a chequerboard array structure is disclosed in PCT Application Number PCT/AU2011/000862, entitled: “Reconfigurable Self Complementary Array”, the contents of which are hereby incorporated by cross reference.

A single-ended, 50-ohm low-noise amplifier cannot successfully be employed as the receiving element for a chequerboard phased-array feed. The amplifer's input impedance is too low, and the amplifier needs to have a differential input. The chequerboard phased-array feed's “natural” impedance is much higher, of the order of 377 ohms, the characteristic impedance of free space. It may be theoretically possible to interpose a balun (short for balanced-to-unbalanced transformer) between a balanced feed and an unbalanced low-noise amplifier, but the inevitable loss of the balun adds directly to the noise temperature of the low-noise amplifier, rendering this approach unworkable.

Furthermore, the optimum noise match impedance of a chequerboard phased-array feed is not purely resistive, but has a reactive (capacitive or inductive) component, and this impedance (a complex quantity) varies as a function of frequency. A low-noise amplifier optimised for use in a chequerboard phased-array feed requires a differential input, high differential-mode input impedance, low common-mode input impedance, and optimum wide-band noise match to a complex, frequency-variable optimum source impedance. Such an amplifier has not previously been realised.

### SUMMARY OF THE INVENTION

It is an object of the invention, in its preferred form to provide an improved form of low noise amplifier.

In accordance with a first aspect of the present invention, there is provided a low noise amplifier circuit including: at least a first input and first output; at least a first stage of transistor amplification having a transistor input terminal; the circuit further comprising: an input driving circuit interconnecting the first input to the transistor input terminal, the input driving circuit including a parallel resonant circuit interconnected between the transistor input terminal and ground and a series resonant circuit interconnected between the input terminal and the transistor input terminal, the input driving circuit functioning as an input matching network for the circuit in conjunction with an input bias and decoupling network.

In some embodiments the resonant circuits are preferably provided by inductive and capacitive components. In some arrangements the capacitive components are preferably formed by package and inter-electrode parasitic capacitances.

In some embodiments, the inductive component of the series resonant circuit can be large and the capacitive component of the series resonant circuit can be small. The inductive component of the series resonant circuit can be above about 14 nH. The inductive component of the parallel resonant circuit can be in the range of 22 to 27 nH.

The low noise amplifier circuit preferably can include at least a first and second stage of transistor amplification.

In some arrangements, the low noise amplifier circuit can be utilised in at least one input to a differential amplifier. In other arrangements, the low noise amplifier circuit can be used in single ended amplifiers.

In accordance with another aspect of the present invention, there is provided a differential mode low noise amplifier including: a first and second single-ended amplifier circuit, said single ended amplifiers circuit performing the amplification of a differential input signal by a multistage to produce a differential output signal, and a second order band pass filter network interconnected to the input of the multistage transistor network; and a combining circuit for combining the differential output signals.

In accordance with a another aspect of the invention, there is provided a differential mode low noise amplifier formed on a printed circuit board (PCB), the PCB including a conductive ground plane substantially covering the PCB, the ground plane having a series of apertures therein; the amplifier including a series of input feeds which can be located centrally on the PCB, with the input feeds being interconnected to the PCB within the apertures located in the ground plane.

### BRIEF DESCRIPTION OF THE DRAWINGS

Embodiments of the invention will now be described, by way of example only, with reference to the accompanying drawings in which:

FIG. 1 illustrates schematically a differential mode low noise amplifier;

FIG. 2 is a circuit drawing of the half-LNA component of the arrangement of FIG. 1;

FIG. 3 illustrates schematically the portions of the simplified input circuit of the half-LNA of the first embodiment;

FIG. 4 illustrates a PCB layout of a pair of differential mode low noise amplifier;

FIG. 5 illustrates the arrangement of FIG. 4 with assembled components;

FIG. 6 illustrates the radiofrequency portion of the circuit of a differential mode low noise amplifier; and

FIG. 7 illustrates the bias supply portion of the circuit of a differential mode low noise amplifier;

### DETAILED DESCRIPTION

The first embodiment provides a differential-input low-noise amplifier of high differential-mode input impedance and moderate common-mode input impedance. The input impedance and optimum noise match impedance are, in the first embodiment, both optimised for the output impedance and optimum noise match impedance which a chequerboard phased-array feed presents it. These features allow the invention to overcome the incompatibility of a single-ended, 50-ohm low-noise amplifier with a chequerboard phased-array feed.

The embodiments provide an advantageous differential single-ended structure, featuring wideband noise and impedance matching to a planar connected array; the optimization of the differential- and common-mode input impedances for operation with a planar connected array. The arrangement is provided in a stably operating low noise amplifier (LNA).

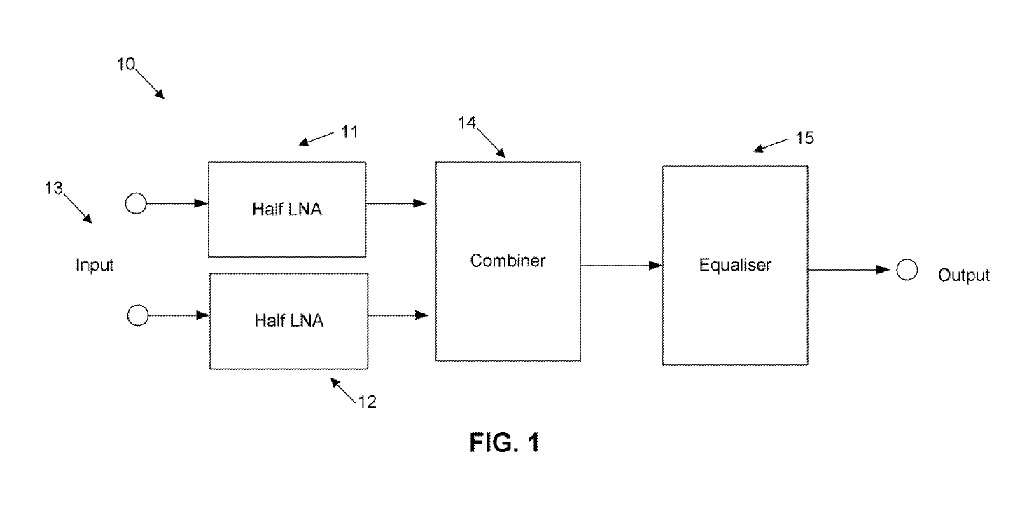

The operational environment for the low noise amplifier is illustrated 10 in FIG. 1. As the amplifier operates in a differential manner, a differential input 13 is received from the feed array. Each arm is subjected to separate amplification by half-LNA amplifiers 11, 12, before being combined 14 and equalised 15. The combiner and equaliser can be of standard construction.

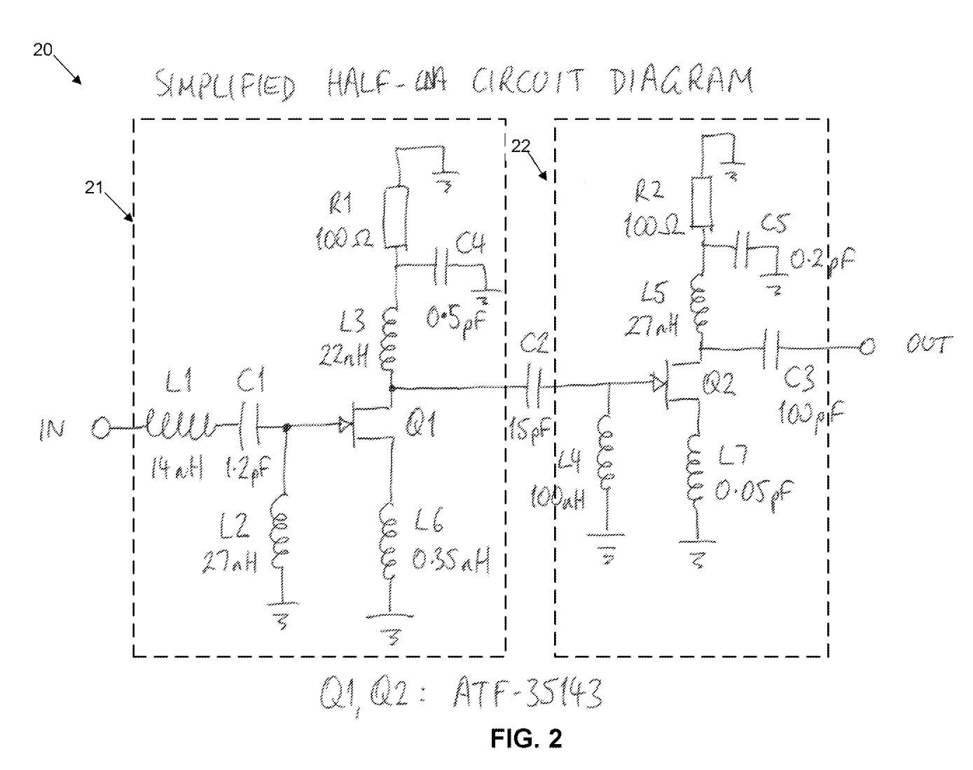

FIG. 2 illustrates a simplified circuit diagram of one of the half-LNAs 20. The half-LNA is a two-stage common-source amplifier having stages 21, 22. The transistors Q1, Q2 used are the Avago ATF-35143. Other transistors may offer improved performance after evaluation. The two stages 21, 22 are capacitively coupled via capacitors C1, C2 and C3, forming the main signal path. The transistor gates are biased via inductors L2 and L4. The drain loads of the transistors are composed by networks R1-C4-L3 and R2-C5-L5 respectively. The source terminals of the transistors are connected to ground through inductors L6 and L7.

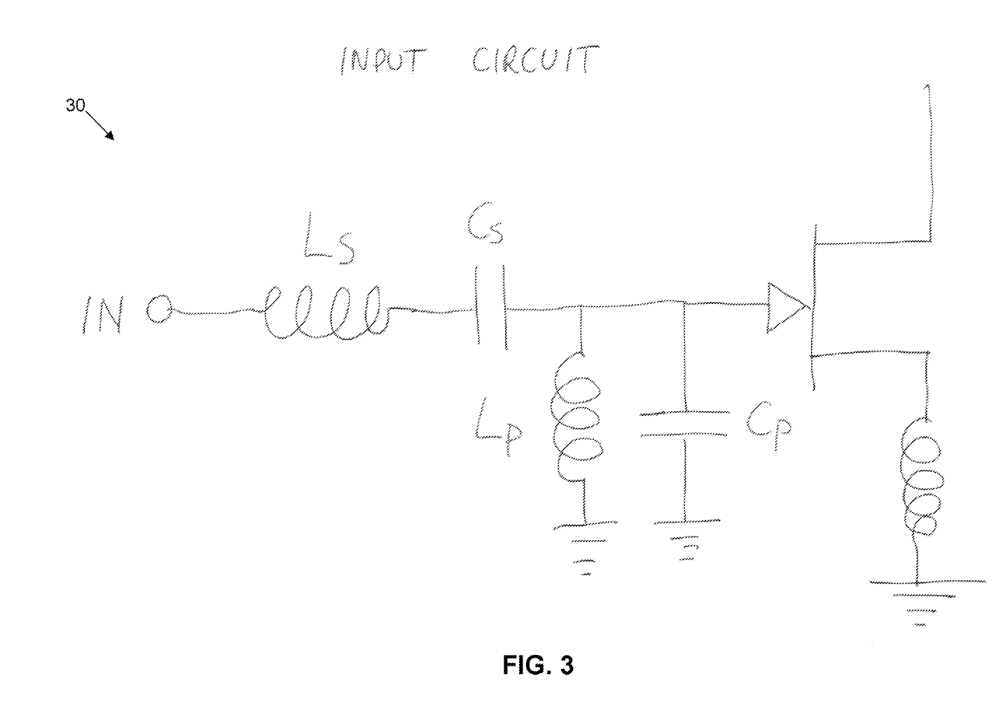

In the first embodiment, the input matching components are absorbed into the input bias and decoupling networks. Wideband low-noise performance results when the input circuit to the first stage transistor Q1 is in the form of a second-order bandpass matching network. Turning to FIG. 3, there is illustrated one such network 30, where a parallel-resonant L-C circuit (Lp and Cp) is connected between the input transistor's gate and ground, and a series L-C circuit (Ls and Cs) is connected between the amplifier's input terminal and the transistor's gate. Inter-electrode and parasitic capacitances account for Cp, the gate bias inductor L2 of FIG. 2 accounts for Lp. The input coupling capacitor C1 of FIG. 2 accounts for Cs. The series inductor L1 of FIG. 2 accounts for Ls.

It should be noted that such a matching technique is also applicable to single-ended low-noise amplifiers.

Returning to FIG. 2, a wideband impedance match also results from the use of this second-order bandpass matching network at the LNA's input. To obtain a high input impedance, L2 has to be small. The lower L2, the higher the input impedance, although at the expense of minimum noise figure. 22 to 27 nH is suitable.

L1 and C1 form part of the input matching network to the LNA. Normal practice is for L1 to be small and C1 to be large. In the first embodiment, L1 is large, and C1 small, so as to produce a large “reactance slope parameter”. Optimum value for L1 is physically unrealizable: around 28 nH. State of the art values are 14 nH for L1 and 1.5 pF for C1. As C1 is reduced and L1 increased in value, the passband shifts downwards in frequency and the minimum noise figure is reduced. A sharp gain peak appears at the bottom of the passband if L1 and C1 are pushed past optimum values. This effect is used to advantage to define a sharp, flat-topped lower band edge.

The drain loads are a 100 ohm resistor (R1 and R2 respectively) in series with an inductor (L3 and L5 respectively), and a small shunt capacitance to ground (C4 and C5 respectively). The main component of the drain load is the resistor. Inductors L3 and L5 may be thought of as providing inductive peaking to define and sharpen the passband shape. They are 22 and 27 nH respectively.

It is difficult to make the LNA stable over a very wide frequency range. Stability may be achieved in the 5-15 GHz region, but at the expense of stability in the UHF band, just below the lower band edge. The LNA's input reflection coefficient can rise above one just below 500 MHz unless L4 is as large as practical. 100 nH is typical. C4 reduces the input reflection coefficient magnitude below-band, at the expense of slightly reduced gain. 0.5 pF is the nominal value.

Inductive source degeneration of the transistors (via L6 and L7) is a known technique for improving the transistors impedance and noise match. The technique must be applied with care, for if too much degeneration is applied, parasitic oscillations in the 5-15 GHz range result. These are caused by parasitic capacitance of the transistor's source leads and circuit board pad capacitance forming a parallel-resonant circuit at microwave frequencies. Source degeneration is not employed on Q2 (L7 is about 0.05 nH). Q1 has only a modest amount of source degeneration to avoid high-frequency parasitic oscillations (L6 is about 0.35 nH, and is embodied as a printed circuit board trace).

In the first embodiment, input capacitance has a deleterious effect. Parasitic capacitance affects performance. The higher the input capacitance, the higher the amplifier's noise figure, the lower the input impedance, and the higher the optimum noise match source impedance. The only good effect of input capacitance is to stabilise the amplifier. As the parasitic capacitance to ground is reduced, Q1 is more prone to high-frequency parasitic oscillations. It is then necessary to reduce Q1's source inductor L6 to stabilise Q1. The reduction in L6 then wipes out most of the improvement in noise figure, input impedance and optimum noise match source impedance resulting from the reduction in shunt capacitance.

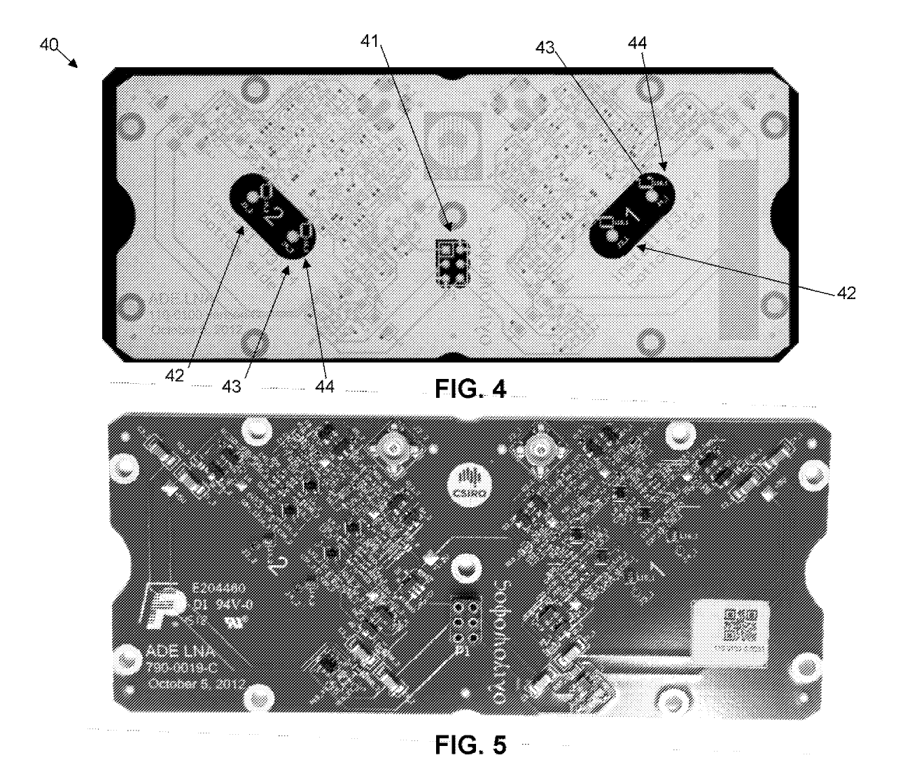

In order to preserve good circuit performance in a high-impedance environment, special layout techniques can be utilised. FIG. 4 illustrates the PCB layout 40. The PCB ground plane is removed around the amplifier's inputs 42, 43 to minimise shunt capacitance. As discussed earlier, L1 is at the upper limit of physically realizable values. This limit is imposed by L1's self-resonant frequency, which decreases as the inductance increases. The self-resonant frequency is influenced strongly by stray capacitance. To keep stray capacitance to a minimum, L1 is situated above the ground-plane cutout 44 and oriented at 45 degrees to the signal flow. In this way connections to its terminals are located as far from each other as practical. The L1-C1 node is a series-resonant point, and is particularly sensitive to stray capacitance. The connection associated with this node is made as small as possible. The transistors Q1 and Q2 are also oriented at 45 degrees to the signal flow, as this orientation allows the shortest signal paths and dis-encumbers Q1's source connections from the other circuit elements. In order for the differential-single-ended architecture to be applied successfully, the total width of a half-section LNA, when laid out on a circuit board, must be less than 10 mm, the feedwire spacing of the chequerboard array. The 45-degree orientation of the transistors allows this width constraint to be observed. To minimise shunt capacitance, particularly at Q1's gate, the bias inductors must be laid out so the signal path passes through the inductors' pad, instead of forming a short stub-line to connect to the bias inductors.

FIG. 5 illustrates the PCB with assembled components.

Returning to FIG. 1, the differential-single-ended amplifier structure 10 consists of two single-ended amplifiers 11, 12 operated in parallel, whose outputs are combined 14 in antiphase to produce an apparently differential input. The single-ended amplifiers' outputs may be combined by any standard technique, such as a push-pull output transformer, or a balun transformer, or a 180-degree hybrid combiner. The first embodiment is a balun transformer, for ease of application and compactness. Nonetheless a balun transformer suffers from imperfect isolation between the input ports. The output network of the LNA is never a perfect impedance match, and a small proportion of the output signal from one side of the LNA is reflected from the load back into the “other” side of the LNA, where it modifies the load impedance seen by the “other” side, which in turn causes the impedance seen at the “other” input to be perturbed. The net effect of this is to unbalance the inputs of the LNA. If the two input ports are labelled 1 and 3, from an S-parameter viewpoint the imperfect isolation between the amplifiers output causes the appearance of cross terms S31 and S13 at the amplifier's inputs. In the first embodiment, these cross terms add to the input terms S11 and S33 in such a way as to increase the differential-mode input impedance (desirable) and reduce the common-mode input impedance (undesirable, as it can result in resonant passband notches). The imperfect balance of the differential-single-ended LNA also causes energy transfer between the common-mode input signal and the output, which effectively reduces the common-mode rejection ratio. A 180-degree hybrid combiner may offer better isolation than a balun transformer, and may offer improved performance.

Finally, the combiner's output is connected to an equalizer circuit 15, the function of which is to flatten the amplifier's passband. The first embodiment of this function is a single-section bridged-T bandpass filter, the centre frequency and bandwidth of which are chosen for best overall amplifier passband flatness.

The first embodiment provides a low noise amplifier optimised for the special requirements of a self complementary array such as the aforementioned chequerboard phased-array feed.

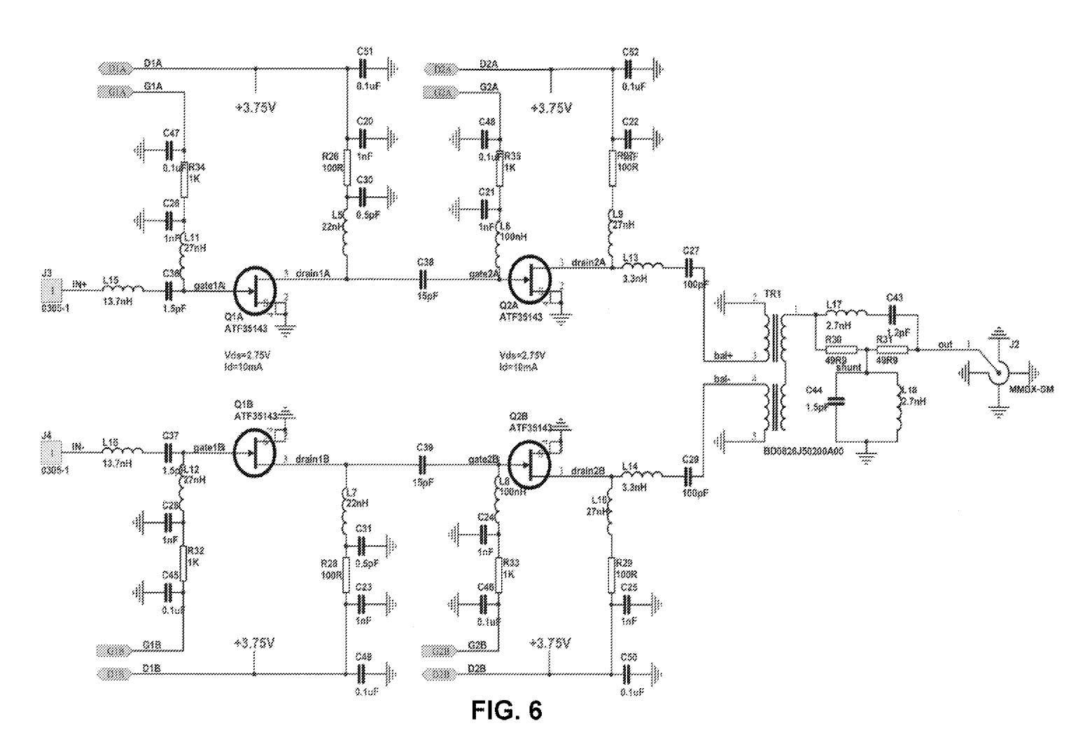

By way of further illustration, FIG. 6 illustrates the radiofrequency portion of the circuit design of a differential mode low noise amplifier.

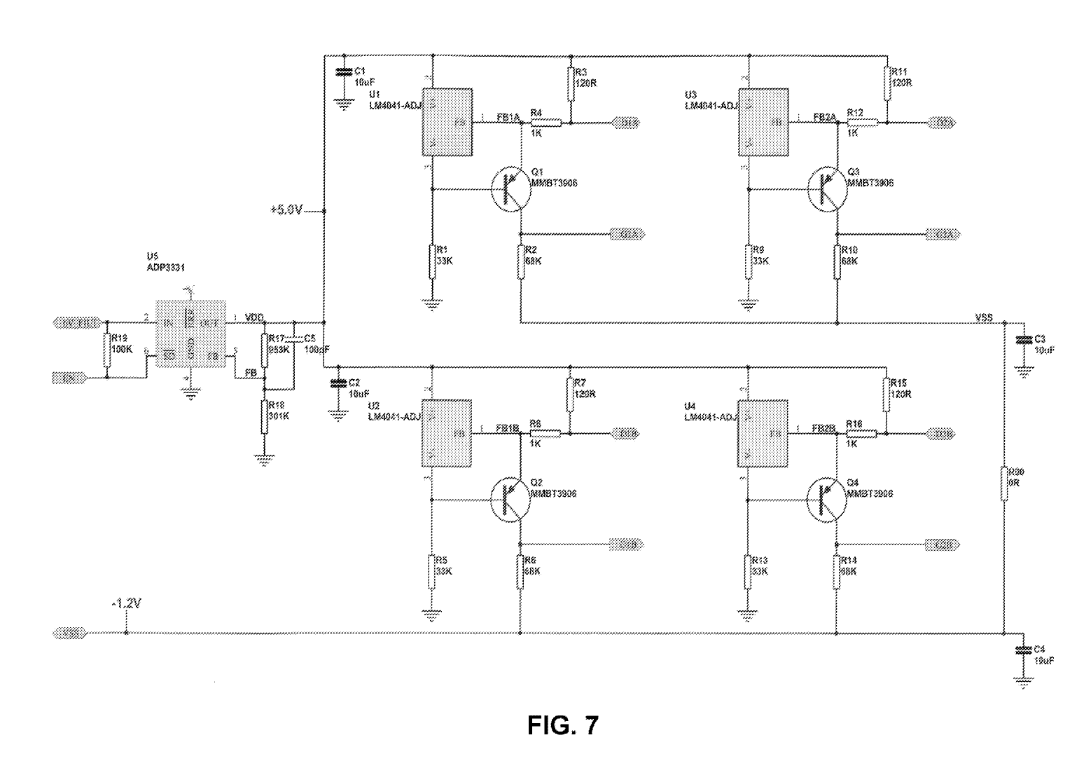

By way of further illustration, FIG. 7 illustrates the bias supply portion of the circuit design of a differential mode low noise amplifier.

The embodiment also has other applications where low noise amplification is required. For example, low noise amplifiers have applications in medical imaging, security scanning, and other forms of sensitive scanning and detection technologies of very weak signals.

Other embodiments can be constructed. For example, where different transistors are used, they will have different operational characteristics which should be individually examined. Different transistors may have different minimum noise temperature. Ideally, the noise parameters of potentially suitable transistors should be separately measured and characterised. One form of suitable alternative transistor was found to be the ATF-38143. If a different transistor is used in the LNA, the component values required for optimum performance may vary. This is particularly the case for the input matching components.

### INTERPRETATION

Reference throughout this specification to “one embodiment”, “some embodiments” or “an embodiment” means that a particular feature, structure or characteristic described in connection with the embodiment is included in at least one embodiment of the present invention. Thus, appearances of the phrases “in one embodiment”, “in some embodiments” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

As used herein, unless otherwise specified the use of the ordinal adjectives “first”, “second”, “third”, etc., to describe a common object, merely indicate that different instances of like objects are being referred to, and are not intended to imply that the objects so described must be in a given sequence, either temporally, spatially, in ranking, or in any other manner.

In the claims below and the description herein, any one of the terms comprising, comprised of or which comprises is an open term that means including at least the elements/features that follow, but not excluding others. Thus, the term comprising, when used in the claims, should not be interpreted as being limitative to the means or elements or steps listed thereafter. For example, the scope of the expression a device comprising A and B should not be limited to devices consisting only of elements A and B. Any one of the terms including or which includes or that includes as used herein is also an open term that also means including at least the elements/features that follow the term, but not excluding others. Thus, including is synonymous with and means comprising.

As used herein, the term “exemplary” is used in the sense of providing examples, as opposed to indicating quality. That is, an “exemplary embodiment” is an embodiment provided as an example, as opposed to necessarily being an embodiment of exemplary quality.

It should be appreciated that in the above description of exemplary embodiments of the invention, various features of the invention are sometimes grouped together in a single embodiment, FIG., or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the Detailed Description are hereby expressly incorporated into this Detailed Description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

Similarly, it is to be noticed that the term coupled, when used in the claims, should not be interpreted as being limited to direct connections only. The terms “coupled” and “connected,” along with their derivatives, may be used. It should be understood that these terms are not intended as synonyms for each other. Thus, the scope of the expression a device A coupled to a device B should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other, including in an electromagnetic coupling sense.

Thus, while there has been described what are believed to be the preferred embodiments of the invention, those skilled in the art will recognize that other and further modifications may be made thereto without departing from the spirit of the invention, and it is intended to claim all such changes and modifications as falling within the scope of the invention. For example, any formulas given above are merely representative of procedures that may be used. Functionality may be added or deleted from the block diagrams and operations may be interchanged among functional blocks. Steps may be added or deleted to methods described within the scope of the present invention.

1. A low noise amplifier circuit including comprising:
at least a first input and first output;
an amplifier input terminal;
a transistor input terminal; and
at least a first stage of transistor amplification, said low noise amplifier circuit further comprising an input driving circuit interconnecting said first input to said transistor input terminal, said input driving circuit including a parallel resonant circuit interconnected between said transistor input terminal and a ground, and a series resonant circuit interconnected between said amplifier input terminal and said transistor input terminal, said input driving circuit functioning as an input matching network for said low noise amplifier circuit in conjunction with an input bias and decoupling network.

2. The low noise amplifier circuit of claim 1, wherein said input driving circuit comprises a second order band pass filter.

3. The low noise amplifier circuit of claim 1, wherein said resonant circuits are provided by inductive and capacitive components.

4. The low noise amplifier circuit of claim 3, wherein said capacitive components of said resonant circuits comprise parasitic capacitances.

5. The low noise amplifier circuit of claim 4, wherein said inductive component of said series resonant circuit is greater than 14 nH and said capacitive component of the series resonant circuit is in the range of 22-27 nH.

6-7. (canceled)

8. The low noise amplifier circuit of claim 1, wherein said circuit includes a second stage of transistor amplification.

9. (canceled)

10. The low noise amplifier circuit of claim 1, wherein said circuit further comprises a conductive ground plane, and wherein said inductive component of said series resonant circuit is spaced apart from said conductive ground plane, wherein parasitic capacitances are minimized.

11. A differential mode low noise amplifier, comprising:
a first and second single-ended amplifier circuit, said first and second single-ended amplifiers circuits being configured to modulate amplification of a differential input signal provided by a multistage transistor network, wherein differential output signals are generated;
a second order band pass filter network in communication with said multistage transistor network; and
a combining circuit configured to combine said differential output signals.

12-13. (canceled)
